(19) United States
(12) Patent Application Publication
(10) Pub. No.: US 2014/0179079 A1
(43) Pub. Date: Jun. 26, 2014

(54) MANUFACTURING METHOD OF LATERAL DOUBLE DIFFUSED METAL OXIDE SEMICONDUCTOR DEVICE

(71) Applicants: Tsung-Yi Huang, HsinChu (TW); Chien-Wei Chiu, Beigan Township (TW)

(72) Inventors: Tsung-Yi Huang, HsinChu (TW); Chien-Wei Chiu, Beigan Township (TW)

(73) Assignee: RICHTEK TECHNOLOGY CORPORATION, R.O.C., Zhupei City (TW)

(21) Appl. No.: 14/044,626

(22) Filed: Oct. 2, 2013

(30) Foreign Application Priority Data
Dec. 25, 2012 (TW) 101149675

(51) Int. Cl. H01L 29/66

(52) U.S. Cl. CPC H01L 29/66681
USPC 438/286

(57) ABSTRACT

The present invention discloses a manufacturing method of a lateral double diffused metal oxide semiconductor (LDMOS) device. The LDMOS device includes: a substrate, an epitaxial layer, a first conductivity type channel stop region, a first conductivity type top region, an isolation oxide region, a field oxide region, a first conductivity type well, a gate, a second conductivity type lightly doped region, a second conductivity type source, and a second conductivity type drain. The present invention defines the channel stop region, the top region, the isolation oxide region, and the field oxide region by a same oxide region mask, wherein the isolation oxide region and the field oxide region are located on the channel stop region and the top region respectively.

### CROSS REFERENCE

The present invention claims priority to TW 101149675, filed on Dec. 25, 2012.

### BACKGROUND OF THE INVENTION

1. Field of Invention

The present invention relates to a manufacturing method of a lateral double diffused metal oxide semiconductor (LDMOS) device; particularly, it relates to such manufacturing method of an LDMOS device wherein a channel stop region, a top region, an isolation oxide region, and a field oxide region are defined by a same oxide region mask.

2. Description of Related Art

FIGS. 1A-1D are schematic cross-section diagrams which show a manufacturing method of front-end process steps of a prior art lateral double diffused metal oxide semiconductor (LDMOS) device 100 with a double reduced surface field (RESURF). As shown in FIG. 1A, an N-type epitaxial layer 11a is formed on a P-type substrate 11. Next, as shown in FIG. 1B, a lithography step defines the implantation region by a photoresist mask layer 12a, and an ion implantation step implants P-type impurities to the defined region in the form of accelerated ions as indicated by the dashed arrow lines shown in the figure to form a channel stop region 12 in the epitaxial layer 11a. Next, as shown in FIG. 1C, a lithography step defines the implantation region by a photoresist mask layer 13a, and an ion implantation step implants P-type impurities to the defined region in the form of accelerated ions as indicated by the dashed arrow lines shown in the figure to form a top region 13 in the epitaxial layer 11a.

Next, as shown in FIG. 1D, an isolation oxide region 14a and a field oxide region 14b are defined by a mask of a silicon nitride layer 14, which is formed by lithography and deposition steps, and the isolation oxide region 14a and the field oxide region 14b are formed by an oxidation and/or deposition step. The isolation oxide region 14a and the field oxide region 14b are for example a shallow trench isolation (STI) structure or a local oxide of silicon (LOCOS) structure, the latter being shown in the figure.

The aforementioned prior art needs three lithography steps to define the channel stop region 12, the top region 13, the isolation oxide region 14a, and the field oxide region 14b. In manufacturing the LDMOS device, especially when the LDMOS device is a discrete device with RESURF, each lithography step significantly increases the manufacturing cost and consumes considerable process time. If any lithography step can be saved, the manufacturing cost and the process time of the LDMOS device can be reduced significantly.

In view of above, to overcome the drawbacks in the prior art, the present invention proposes a manufacturing method of an LDMOS device, which reduces the manufacturing cost and shortens the manufacturing process time.

### SUMMARY OF THE INVENTION

The present invention provides a manufacturing method of a lateral double diffused metal oxide semiconductor (LDMOS) device, including: providing a substrate; forming an epitaxial layer on the substrate; forming an oxide region mask on the epitaxial layer; forming a channel stop region having a first conductivity type and a top region having the first conductivity type in the epitaxial layer according to the oxide region mask; forming an isolation oxide region and a field oxide region above the channel stop region and top region according to the oxide region mask respectively; removing the oxide region mask; forming a well having the first conductivity type in the epitaxial layer; forming a gate on the epitaxial layer, wherein part of the gate is located on the field oxide region, and another part of the gate is located on the well; forming a lightly doped region having a second conductivity type in the well, wherein at least part of the lightly doped region is beneath the gate; and forming a source and a drain having the second conductivity type at different sides of the gate, in the well and in the epitaxial layer respectively, whereby when the LDMOS device is turned ON, a lateral current channel is formed between the source and the drain.

In one preferable embodiment, the manufacturing method further includes: forming a drift region having the second conductivity type in the epitaxial layer, wherein the drift region is connected to the drain, and separated from the source by the well.

In another preferable embodiment, the channel stop region includes a high density region and a low density region, wherein the high density region is located between the low density region and the isolation oxide region.

In another preferable embodiment, the channel stop region and the top region are formed by a same impurity doping step.

In the aforementioned embodiment, preferably, the impurity doping step includes an ion implantation step, and the step of forming the channel stop region and the top region includes: defining the channel stop region and the top region by the oxide region mask, and implanting the first conductivity type impurities to the defined region in the form of accelerated ions by the ion implantation step.

In one another preferable embodiment, the oxide region mask includes a silicon nitride layer.

In one another preferable embodiment, the lightly doped region is connected to the source.

In one another preferable embodiment, the field oxide region and the top region are defined at a same region by the oxide region mask from top view, and the isolation oxide region and the channel stop region are defined at another same region by the oxide region mask from top view.

In one another preferable embodiment, the LDMOS device includes a double reduced surface field (RESURF) LDMOS device.

In one another preferable embodiment, the double RESURF LDMOS device is a discrete device.

The objectives, technical details, features, and effects of the present invention will be better understood with regard to the detailed description of the embodiments below.

### BRIEF DESCRIPTION OF THE DRAWINGS

FIGS. 1A-1D are schematic cross-section diagrams which show a manufacturing method of front-end process steps of a prior art lateral double diffused metal oxide semiconductor (LDMOS) device 100.

FIGS. 2A-2G show a first embodiment of the present invention.

FIG. 3 shows a second embodiment of the present invention.

FIG. 4 shows a third embodiment of the present invention.

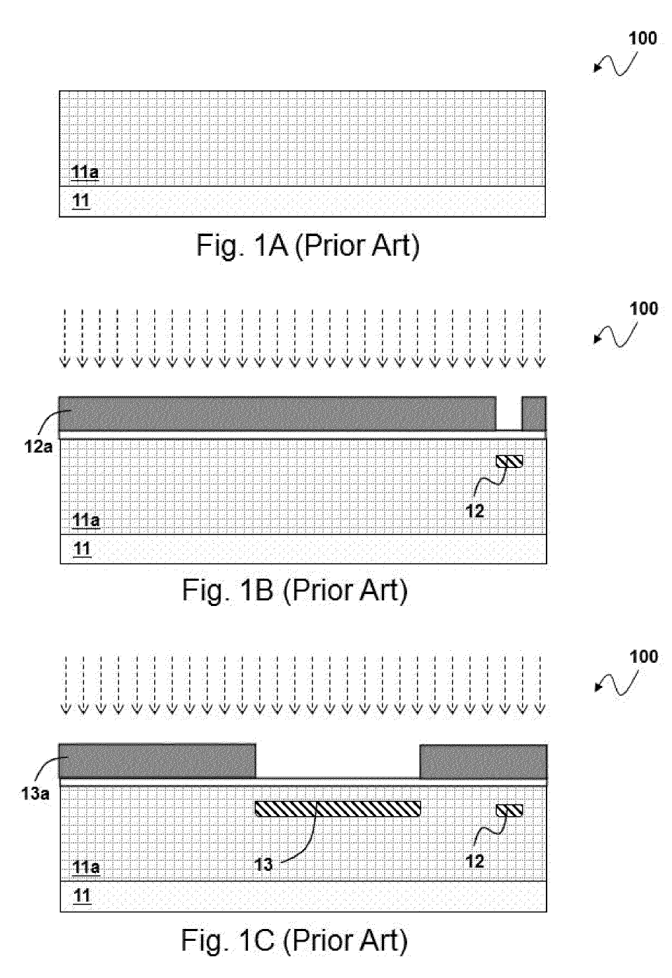

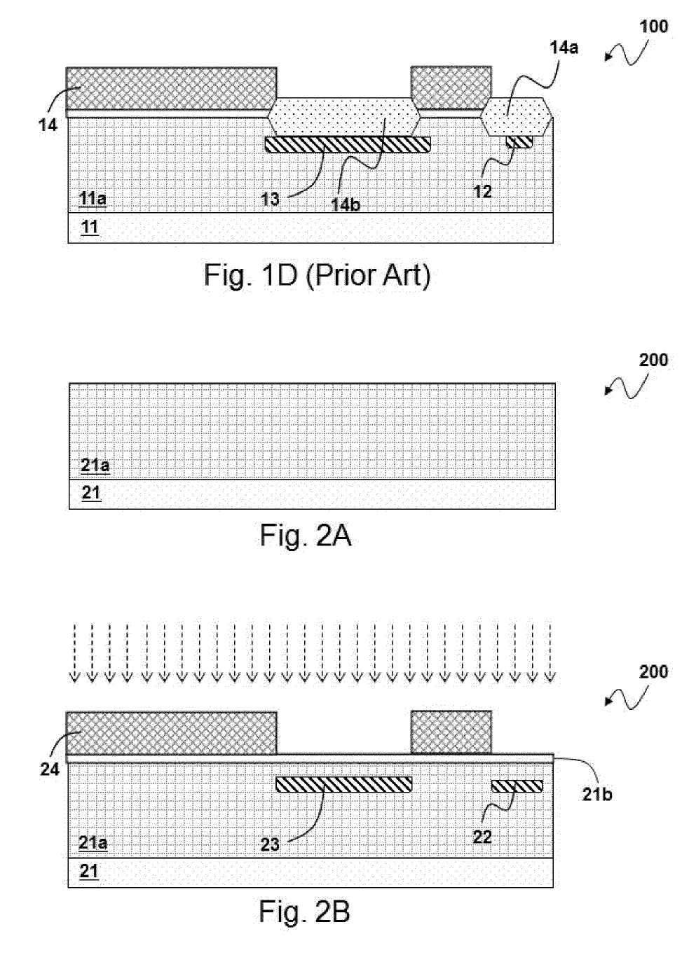

### DESCRIPTION OF THE PREFERRED EMBODIMENTS

The drawings as referred to throughout the description of the present invention are for illustration only, to show the interrelations between the regions and the process steps, but not drawn according to actual scale.

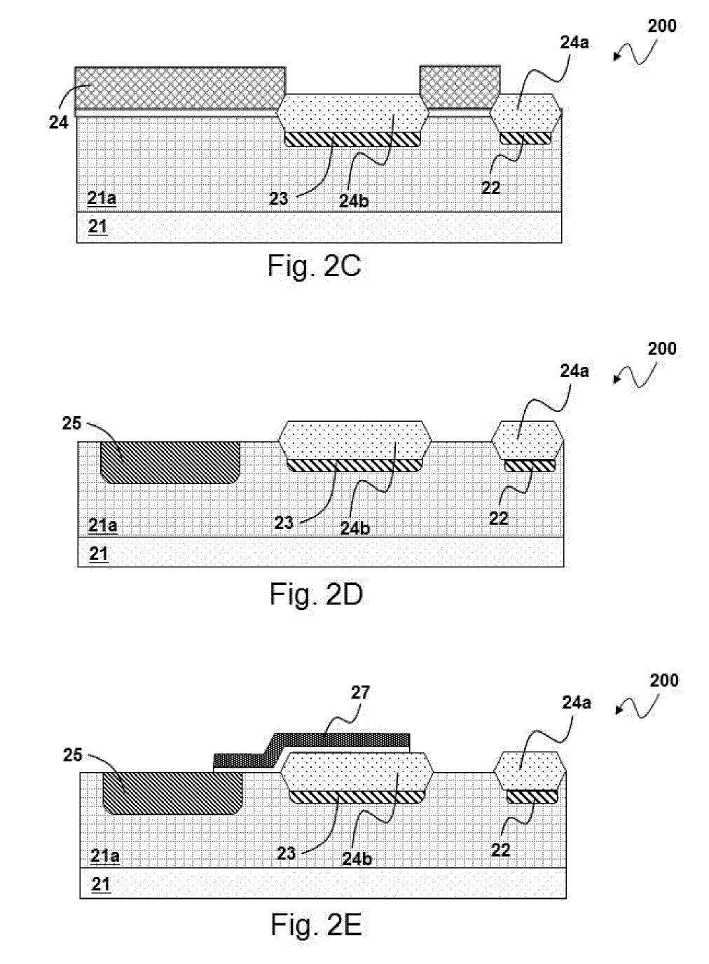

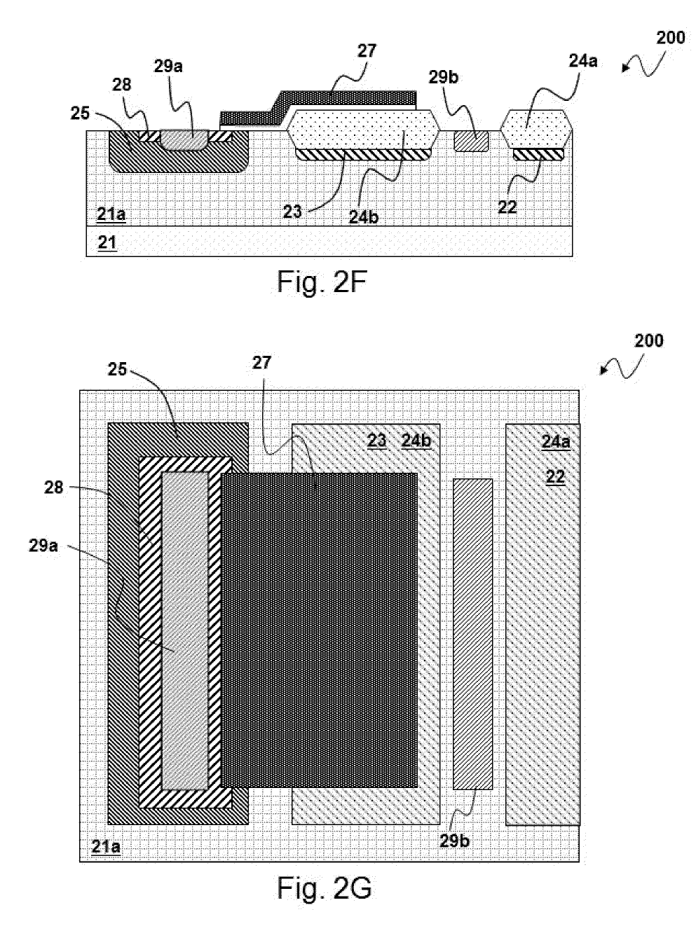

Please refer to FIGS. 2A-2G for a first embodiment according to the present invention, wherein FIGS. 2A-2F are schematic cross-section diagrams of an LDMOS device 200, and FIG. 2G shows a top view of FIG. 2F. As shown in FIG. 2A, a substrate 21 which is for example but not limited to P-type is provided, and an epitaxial layer 21a which is for example but not limited to N-type is formed on the substrate 21. Next, referring to FIG. 2B, an oxidation region mask 24 is formed on the epitaxial layer 21a, wherein the oxidation region mask 24 is for example but not limited to a silicon nitride layer. Note that when the oxidation region mask 24 is the silicon nitride layer, a preferable embodiment to form the oxidation region mask 24 is that, as shown in FIG. 2B, a pad oxide layer 21b is formed on the epitaxial layer 21a first, and then the silicon nitride layer is formed on the pad oxide layer 21b, to mitigate the stress between the silicon nitride layer and the epitaxial layer 21a.

Referring to FIG. 2B, the oxidation region mask 24 for example is used as a hard mask to define a channel stop region 22 and a top region 23, and an ion implantation step is performed, which implants for example but not limited to P-type impurities to the defined region in the form of accelerated ions as indicated by the dashed lines shown in the figure, to form the P-type channel stop region 22 and the P-type top region 23 in the epitaxial layer 21a. Note that the channel stop region 22 and the top region 23 are formed by a same impurity doping step (such as the ion implantation step in this embodiment).

Next, referring to FIG. 2C, an isolation oxide region 24a and a field oxide region 24b above the channel stop region 22 and top region 23 respectively are formed according to the oxide region mask 24, for example by an oxidation and/or a deposition step. The isolation oxide region 24a and the field oxide region 24b for example are the STI structure or the LOCOS structure, the latter being shown in the figure. If the oxide regions 24a and 24b are the STI structure, an etch step should be performed before the deposition step. Note that, the ion implantation step which forms the channel stop region 22 and the top region 23 may be performed before or after the isolation oxide region 22 and the field oxide region 23 are formed, and both fall within the scope of the present invention.

Next, referring to FIG. 2D, after removing the oxide region mask, a well 25 which is for example but not limited to P-type is formed in the epitaxial layer 21a by for example but not limited to a lithography step and an ion implantation step. Referring to FIG. 2E, a gate 27 is formed on the epitaxial layer 21a, wherein part of the gate 27 is located on the field oxide region 24b, and another part of the gate 27 is located on the well 25.

Next, referring to FIG. 2F, a lightly doped region 28 which is for example but not limited to N-type is formed in the well 25. At least part of the lightly doped region 28 is located beneath the gate 27, such that a lateral current channel can be formed when the LDMOS device 200 is turned ON. Next, as shown in the figure, a source 29a and a drain 29b which are for example but not limited to the N-type are formed at different sides of the gate 27, in the well 25 and in the epitaxial layer 21a respectively. When the LDMOS device 200 is turned ON, the lateral current channel is formed between the source 29a and the drain 29b. Preferably, the lightly doped region 28 is connected with the source 29a.

This embodiment is different from the prior art in that, in this embodiment, the channel stop region 22, the top region 23, the isolation oxide region 24a, and the field oxide region 24b are defined by the same oxide region mask 24, while the prior art needs three different lithography steps to define the aforementioned regions. Besides, in this embodiment, the channel stop region 22 and the top region 23 may be formed by the same impurity doping step. Therefore, the present invention not only decreases the manufacturing cost, but also reduces the manufacturing steps and time.

FIG. 2G shows a top view of FIG. 2F, which shows an example of the layout of the regions of the LDMOS device 200 from top view. The example of FIG. 2G shows that, the field oxide region 24b and the top region 23 are defined in the same region by the oxidation region mask 24, and the isolation oxide region 24a and the channel stop region 22 are defined in another same region by the oxidation region mask 24, so the field oxide region 24b overlap with the top region 23, and the isolation oxide region 24a overlap with the channel stop region 22.

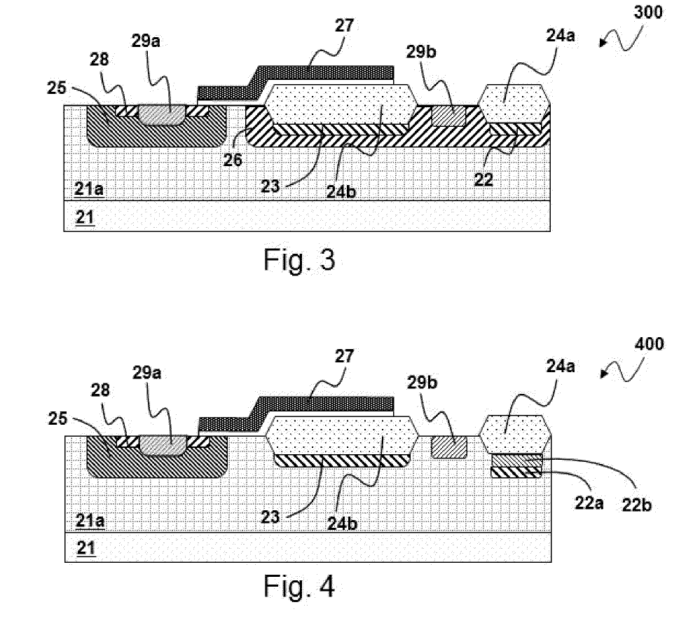

Please refer to FIG. 3 for a second embodiment according to the present invention, wherein FIG. 3 shows a drift region 26 which is formed in the epitaxial 21a by adding a few process steps to the manufacturing method of the LDMOS device 200 as shown in the first embodiment. The drift region 26 has a conductivity type for example but not limited to N-type. The drift region 26 is connected to the drain 29b, and the drift region 26 and the source 29a are separated by the well 25. Therefore, an LDMOS device 300 is formed as shown in the figure. In a preferable embodiment, when the epitaxial layer 21a is P-type, the drift region 26 helps to form the current channel. In another embodiment, when the epitaxial layer 21a is N-type, the drift region 26 maybe omitted (or it may still be included if desired).

FIG. 4 shows a third embodiment of the present invention. This embodiment is an example showing that the channel stop region includes a high density region 22b and a low density region 22a, which are formed by adding one implantation process step in the manufacturing method of the LDMOS device 200. An LDMOS device 400 is formed as shown in FIG. 4. As shown in the figure, the high density region 22b is located between the low density region 22a and the isolation oxide region 24a. One advantage of this embodiment is that, when the LDMOS device 400 operates in an ultra-high voltage of several-hundred volts, because the high density region 22b has a relatively higher impurity density than the low density region 22a, a mis-operation caused by “field device turning ON” may be prevented.

Note that an LDMOS device according to the present invention may include for example but not limited to a double reduced surface field (RESURF) LDMOS device. By way of example, the LDMOS device 200 of the first embodiment may have an upper RESURF region formed between the top region 23 and the epitaxial region 21a, and a lower RESURF region formed between the epitaxial layer 21a and the substrate 21. In the second example, the LDMOS device 300 may have an upper RESURF region formed between the top region 23 and the drift region 26, and a lower RESURF region formed between the drift region 26 and the epitaxial layer 21a. The aforementioned RESURF LDMOS device is for example but not limited to a discrete device, which cooperates with other circuits or devices to form a functional circuit.

The present invention has been described in considerable detail with reference to certain preferred embodiments thereof. It should be understood that the description is for illustrative purpose, not for limiting the scope of the present invention. Those skilled in this art can readily conceive variations and modifications within the spirit of the present invention. For example, other process steps or structures which do not affect the primary characteristic of the device, such as a threshold voltage adjustment region, etc., can be added; for another example, the lithography step described in the above can be replaced by electron beam lithography, X-ray lithography, etc.; for another example, in all the aforementioned embodiments, the conductivity type of each of the drift region, the source, the drain, and the lightly doped region, etc. is not limited to N-type, and the conductivity type of each of the well, the channel stop region, and the top region, etc. is not limited to N-type, but it may be changed to P-type (or N-type) with corresponding modifications of the conductivity type and/or impurity concentration in other regions; for another example, the substrate and the epitaxial layer are not limited to the conductivity type in the embodiments, but it may be changed to the opposite conductivity type with corresponding modifications of the conductivity type and/or impurity concentration in other regions. In view of the foregoing, the spirit of the present invention should cover all such and other modifications and variations, which should be interpreted to fall within the scope of the following claims and their equivalents. An embodiment or a claim of the present invention does not need to achieve all the objectives or advantages of the present invention. The title and abstract are provided for assisting searches but not for limiting the scope of the present invention.

What is claimed is:

1. A manufacturing method of a lateral double diffused metal oxide semiconductor (LDMOS) device, comprising:
providing a substrate;
forming an epitaxial layer on the substrate;
forming an oxide region mask on the epitaxial layer;
forming a channel stop region having a first conductivity type and a top region having the first conductivity type in the epitaxial layer according to the oxide region mask;
forming an isolation oxide region and a field oxide region above the channel stop region and top region according to the oxide region mask respectively;
removing the oxide region mask;
forming a well having the first conductivity type in the epitaxial layer;
forming a gate on the epitaxial layer, wherein part of the gate is located on the field oxide region, and another part of the gate is located on the well;
forming a lightly doped region having a second conductivity type in the well, wherein at least part of the lightly doped region is beneath the gate; and
forming a source and a drain having the second conductivity type at different sides of the gate, in the well and in the epitaxial layer respectively, whereby when the LDMOS device is turned ON, a lateral current channel is formed between the source and the drain.

2. The manufacturing method of claim 1 further comprising: forming a drift region having the second conductivity type in the epitaxial layer, wherein the drift region is connected to the drain, and separated from the source by the well.

3. The manufacturing method of claim 1, wherein the channel stop region includes a high density region and a low density region, in which the high density region is located between the low density region and the isolation oxide region.

4. The manufacturing method of claim 1, wherein the channel stop region and the top region are formed by a same impurity doping step.

5. The manufacturing method of claim 4, wherein the impurity doping step includes an ion implantation step, and the step of forming the channel stop region and the top region includes: defining the channel stop region and the top region by the oxide region mask, and implanting the first conductivity type impurities to the defined region in the form of accelerated ions by the ion implantation step.

6. The manufacturing method of claim 1, wherein the oxide region mask includes a silicon nitride layer.

7. The manufacturing method of claim 1, wherein the lightly doped region is connected to the source.

8. The manufacturing method of claim 1, wherein the field oxide region and the top region are defined at a same region by the oxide region mask from top view, and the isolation oxide region and the channel stop region are defined at another same region by the oxide region mask from top view.

9. The manufacturing method of claim 1, wherein the LDMOS device includes a double reduced surface field (RESURF) LDMOS device.

10. The manufacturing method of claim 9, wherein the double RESURF LDMOS device is a discrete device.
